(19) United States
(12) Patent Application Publication
(10) Pub. No.: US 2013/0038358 A1
(43) Pub. Date: Feb. 14, 2013

(54) WIRELESS SENSOR NODE AND METHOD

(71) Applicants: David M. Cook, Corvallis, OR (US); Andrew L. Van Brocklin, Corvallis, OR (US)

(72) Inventors: David M. Cook, Corvallis, OR (US); Andrew L. Van Brocklin, Corvallis, OR (US)

(21) Appl. No.: 13/206,754

(22) Filed: Aug. 10, 2011

(51) Int. Cl. H03L 7/00

(52) U.S. Cl. 327/141

(57) ABSTRACT

Determining time latency at a sensor node in a mesh network. A beacon time is received at the sensor node from an upstream node, the beacon time offset from global time by the latency. The latency, the global time, and a corresponding local time are determined at the sensor node.

### BACKGROUND

Wireless sensor nodes may used in a variety of applications. One such application is seismic monitoring for use in various endeavors such as oil exploration, study of plate tectonics, and so on. In these and other uses, a large number of such sensor nodes disposed at different locations over a multiple-kilometer area may measure and collect data on the same event.

In such applications, the sensor nodes are typically positioned where they do not have access to the electrical grid, so their electrical power is self-contained. In addition, it is frequently desired that the sensors collect data at certain intervals over an extended period of time, and store this data in a record for each interval. As such, it is desirable to reduce or minimize the electrical power usage of a node, in order to allow the sensors to operate for a longer time without replacement or replenishment of their power source.

Analyzing the data collected from multiple sensors includes correlating the data collected at a given time by one sensor with the data collected at the same given time by other sensors. To determine the time associated with the collected data, a sensor may include an on-board time resource, such as a global positioning system (GPS) receiver, which is operated as needed to provide a sufficiently accurate time value for all of the data records. The on-board time resource, unfortunately, typically consumes a significant amount of electrical power during operation. This results in increased electrical power usage by the node, which in turn reduces the length of time in which the sensor can operate without replacement or replenishment of its power source.

### BRIEF DESCRIPTION OF THE DRAWINGS

FIG. 1 is a schematic representation of a wireless sensor mesh network system in accordance with an embodiment of the present disclosure.

FIG. 2 is a schematic representation of an example time latency resulting from hopping beacon times from one wireless sensor node to another of the system of FIG. 1 in accordance with an embodiment of the present disclosure.

FIG. 3 is a block diagram of a wireless sensor node usable in the system of FIG. 1 in accordance with an embodiment of the present disclosure.

FIG. 4 is a schematic representation of timing beacons and GPS PPS signals received by the wireless sensor node of FIG. 3 in accordance with an embodiment of the present disclosure.

FIGS. 5A-B are flowcharts according to an embodiment of the present disclosure of a method of time-synchronizing a wireless sensor node of a mesh network.

FIG. 6 is a schematic representation of an example correction of time latency achieved using the method of FIGS. 5A-B in accordance with an embodiment of the present disclosure.

FIGS. 7A-B are flowcharts according to an embodiment of the present disclosure of another method of time-synchronizing a wireless sensor node of a mesh network.

FIGS. 8A-B are flowcharts according to an embodiment of the present disclosure of yet another method of time-synchronizing a wireless sensor node of a mesh network.

FIG. 9 is a schematic representation of an example correction of time latency achieved using the methods of FIGS. 7A-B and 8A-B in accordance with an embodiment of the present disclosure.

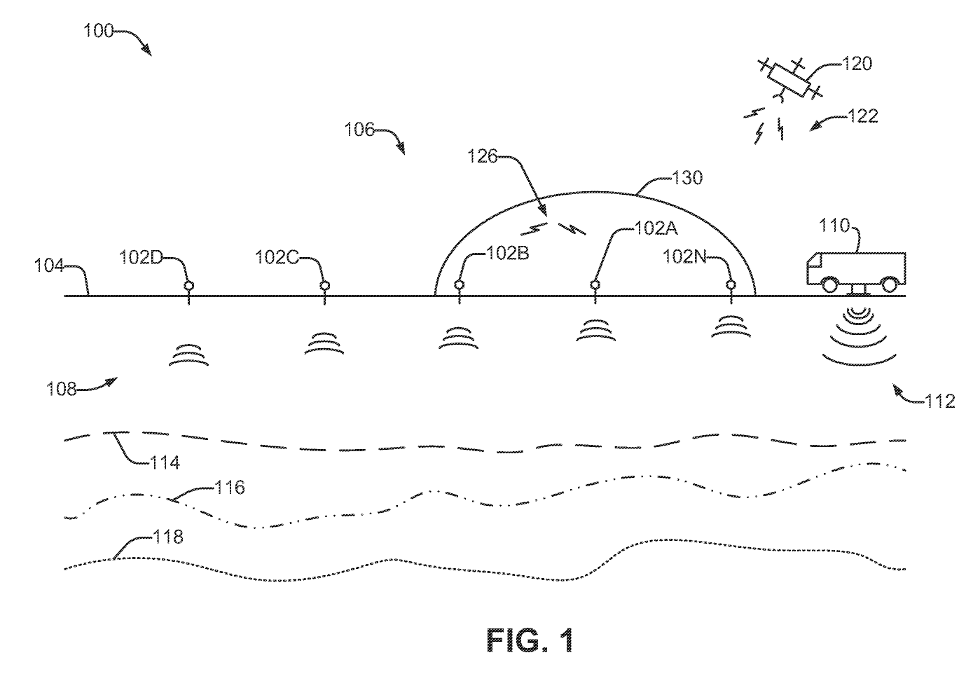

### DETAILED DESCRIPTION

Analyzing the data collected from multiple sensors includes correlating the data collected at a given time by one sensor with the data collected at the same given time by other sensors. To determine the time associated with the collected data, a sensor may include an on-board time resource, such as a global positioning system (GPS) receiver, which is operated as needed to provide a sufficiently accurate time value for all of the data records. The on-board time resource, unfortunately, typically consumes a significant amount of electrical power during operation. This results in increased electrical power usage by the node, which in turn reduces the length of time in which the sensor can operate without replacement or replenishment of its power source.

Referring now to the drawings, there is illustrated an example of a wireless sensor node in a mesh network. A wireless transceiver in the sensor node receives, from an upstream node in the network, a time value (referred to as “beacon time”, or “hopped time”) which corresponds to global time as sent by the transmitter of the upstream node's wireless transceiver. An undetermined latency delay in communication of the time value through the upstream node's transmitter and the sensor node's receiver causes the beacon time as received at the sensor to be offset from global time by the latency. The sensor node uses a power-consuming resource to determine the global time, and computes the latency using the hopped time and the global time. For values of beacon time subsequently received by the node, the node uses the latency to compute the global time corresponding to the beacon time, without using the power-consuming resource. For each beacon time, a timestamp including the global time and the corresponding local time provided by an on-board clock is recorded. Power is conserved at the sensor node by determining global time for the subsequent receptions of beacon times without using the power-consuming resource. The resulting reduction or minimization in power usage advantageously allows the sensor node to operate for a longer period of time without replacement or replenishment of its power source.

Considering now a schematic view of a system that is illustrative and non-limiting with respect to the present teachings, a system 100 includes a plurality of wireless seismic sensor nodes 102, such as sensor nodes 102A through 102D and 102N. The respective nodes 102 are distributed over a land surface 104 such that a sensor array 106 is defined. Each seismic sensor node 102 is configured to sense or detect incident seismic energy 108 and to digitally quantify corresponding seismic data. In one example, each node 102 samples the incident seismic energy 108 at a rate of five-hundred times per second. Other digital sampling rates can also be used. Each node 102 includes an onboard local clock configured to provide a local clock time value. Each node 102 is further configured to store the seismic data and respective timestamps on an ongoing basis.

The system 100 may also include a source of artificial seismic energy 110. In some examples, the source 110 may be embodied as a truck or and vehicle having electro-mechanical resources configured to produce an outgoing seismic stimulus 112. Generally and without limitation, the outgoing seismic stimulus 112 is reflected and refracted by way of various subterranean strata and features 114, 116 and 118. The reflected and/or refracted energy results in seismic energy 108 incident to the respective nodes 102. The precise definition or constituency of such features 114-118 not germane to an understanding of the present teachings, and further elaboration is not needed herein. The seismic data associated with the seismic energy 108 sensed by the set of nodes in the sensor array 106 in response to the seismic stimulus 112 is typically post-processed at a data center. The timestamps are used during post-processing to correlate or cross-correlate the seismic data among the various nodes 102. The seismic data may also be correlated to the global time. The accuracy with which the seismic data can be correlated is dependent in part upon the accuracy of the time values contained in the timestamps.

The system 100 further includes a global positioning system (GPS) satellite 120. The satellite 120 is illustrative of any of a plurality of such GPS satellites in Earth orbit. The satellite 120 provides global time values by way of wireless signaling 122. As defined herein and in the appended claims, the term “global time” shall be broadly understood to mean a time value provided by, or traceable to, a national or international standards entity such as an atomic clock or other resource. Some or all of the seismic sensor nodes 102 may be configured to directly receive global time by way of the wireless signaling 122. The corresponding nodes 102 perform such time value reception on an intermittent basis, such as periodically, in response to a predefined event, or in accordance with another suitable scheme. Reception of global time at a node 102 consumes a significant amount of power, so in order to conserve power each seismic sensor node 102 is configured to acquire global time by way of the signaling 122 sparingly, a few times per day for example.

The sensor array 106 may, in some examples, take the form of a wireless mesh network of the sensor nodes 102. As defined herein and in the appended claims, the term “mesh network” shall be broadly understood to mean a network topology in which nodes serve to relay (or “hop”) data to other nodes along defined paths. The paths may be defined as the network is brought up, and may be re-defined as individual nodes join the network (e.g. by powering up), or leave the network (e.g. by powering down).

A particular node 102 in a wireless mesh network may be configured to receive a time value from an upstream node 102 in its defined path via a wireless signaling mechanism 126. For example, each node 102 may include a wireless transceiver that operates according to the IEEE 802.11 communication standard for implementing wireless local area networks in order to implement the wireless signaling mechanism 126. The time value transmitted from one node to another via the wireless signaling mechanism 126 is referred to herein as beacon time. As defined herein and in the appended claims, the term “beacon time” shall be broadly understood to mean a time value received via the wireless signaling mechanism 126 at a node in the mesh network from an upstream node in the mesh network. The beacon time may be transmitted from one node to another via the wireless signaling mechanism 126 in the same manner as any other data, or through a special-purpose time data mechanism.

Consider an example path in the mesh network in which data, such as a time value, is hopped from node 102A to node 102B, then from node 102B to node 102C, and finally from node 102C to node 102D. The wireless transceiver of node 102A has a wireless communications range 130 that allows it to communicate with node 102B and node 102N. However, the range of node 102A is insufficient to wirelessly communicate directly with nodes 102C and 102D. Similarly, node 102B has the range to wirelessly communicate with nodes 102A, 102C, and node 102C has the range to wirelessly communicate with nodes 102B, 102D. This arrangement allows data to be relayed from node 102A to node 102D in a total of three hops. Moreover, it advantageously allows the use in each node 102 of a wireless transceiver that consumes less power, thus conserving the power source of the node 102.

In preparation for transmitting, the upstream node typically sets the beacon time to a value that the upstream node considers to be global time. However, a time latency or delay occurs during the transmission process that in turn causes the beacon time received at the receiving node to be different from global time. The majority of the latency is due to the time it takes to send the data through the transmitter of the upstream node and to receive the data through the receiver of the receiving node. For a given pair of nodes 102, the latency typically is relatively constant from transmission to transmission. However, a change in the topology of the network, and particularly a change in the identity of the upstream node, can change the latency.

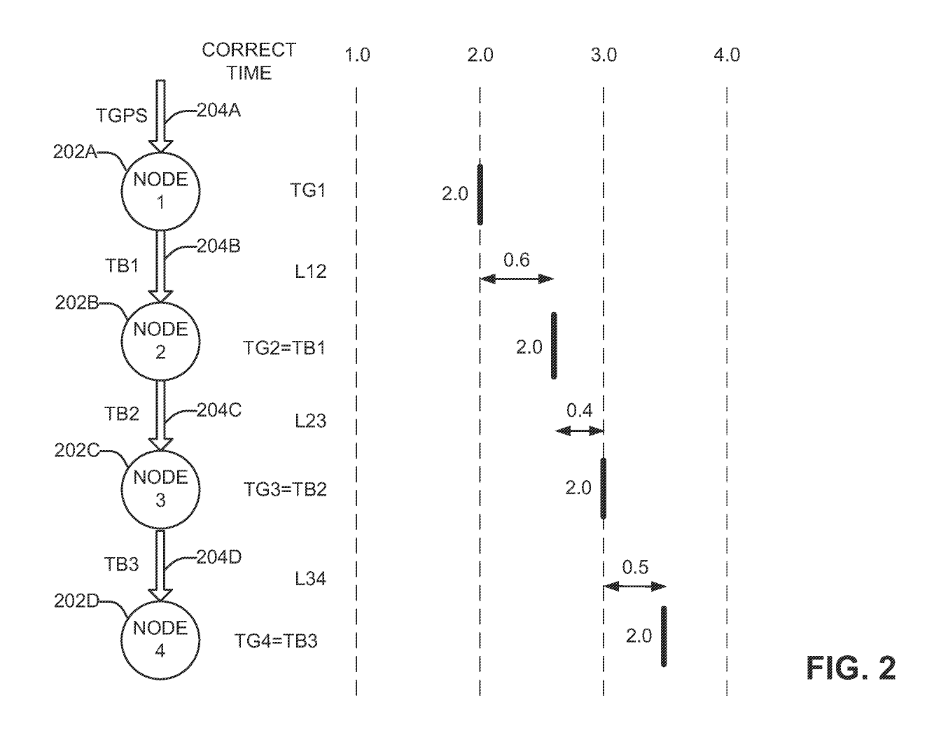

Consider now, and with reference to FIG. 2, the effect of latency in the hopping of beacon times between nodes. FIG. 2 illustrates four nodes 202A-D. In one example, seismic sensor nodes 202A-D may correspond to sensor nodes 102A-D respectively. Each node 202A-D maintains its own internal version of what it believes to be global time. For purposes of illustration, assume that each node is configured to receive beacon time from an upstream node, update its internal global time based on the beacon time, and then transmit its internal global time to the next downstream node with substantially no delay. In this example operation, node1 202A receives the correct global time TGPS 204A from its GPS receiver, and sets its internal global time TG1 to match it. The local clock of node1 202A increments the internal global time TG1 to track the correct global time. Then, at global time 2.0 seconds, node1 202A transmits to node2 202B the beacon time TB1 204B, which has the value of 2.0 seconds corresponding to its internal global time TG1. Node2 202B, upon receipt, sets its internal global time TG2 to 2.0 seconds, based on the beacon time TB1 204B. However, due to the latency L12 of 0.6 seconds that occurs during the transmission between nodes, the correct global time is now 2.6 seconds. Next, node2 202B substantially immediately transmits to node3 202C the beacon time TB2 204C, which has the value of 2.0 seconds, corresponding to the internal global time TG2 of node2 202B. Node3 202C, upon receipt, sets its global time TG3 to 2.0 seconds based on the beacon time TB2 204C. However, due to the latency L23 of 0.4 seconds that occurs during the transmission between these nodes, the correct global time is now 3.0 seconds. Finally, node3 202C substantially immediately transmits to node4 202C a beacon time TB3 204D, which has the value of 2.0 seconds, corresponding to the global time TG3 of node 3 202C. Node4 202D, upon receipt, sets its global time TG4 to 2.0 seconds based on the beacon time TB3 204D. However, due to the latency L34 of 0.5 seconds that occurs during the transmission between these nodes, the correct global time is now 3.5 seconds. It can be seen that the internal global time value of a node deviates further from the correct global time with every additional hop. The resulting inaccuracies in the timestamps generated by these nodes can make correlation of the seismic data between the various nodes difficult or impossible.

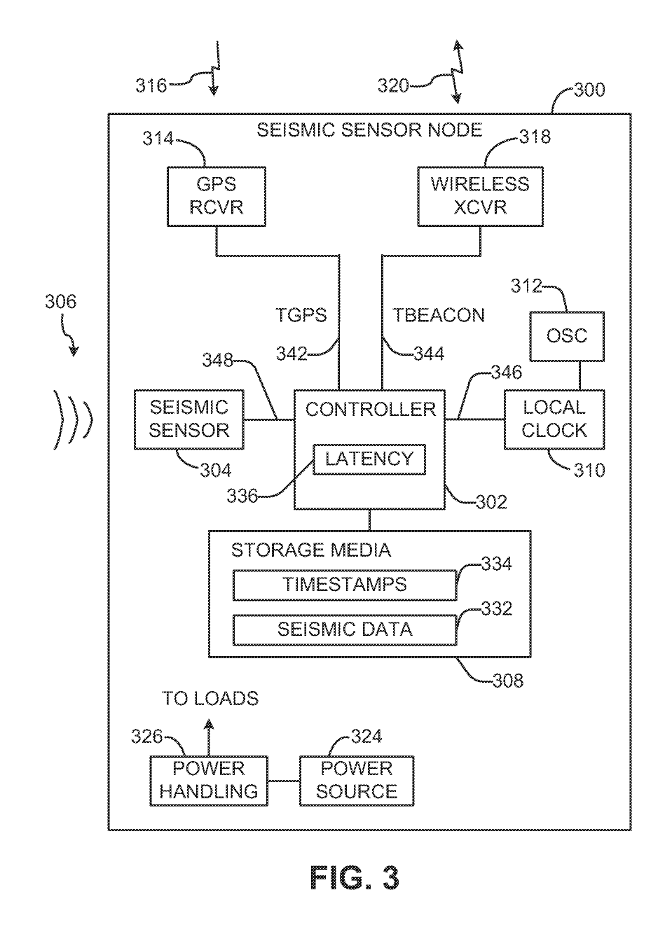

Consider now, with reference to FIG. 3, a block diagram of a wireless sensor node 300. The node 300 is illustrative and non-limiting with respect to the present teachings. Thus, other apparatuses, nodes or systems can be configured and/or operated in accordance with the present teachings. In one example, each seismic sensor node 102 is substantially defined by the node 300.

The node 300 includes power handling circuitry 326 configured to receive electrical energy from a power source 324, such as for example a storage battery, and to provide conditioned or regulated power to the various resources and circuits of the node 300. Non-limiting examples of operations performed by the power handling 326 include voltage regulation, current limiting, and so on.

The node 300 includes a controller 302. The controller 302 is configured to control various operations of the node 300. The controller 302 can be defined by or include any suitable resources such as, without limitation, a microprocessor, a microcontroller, a state machine, an application specific integrated circuit (ASIC), digital or analog or hybrid circuitry, and so on. In one example, the controller 302 is configured to operate in accordance with a computer-readable program code.

The node 300 also includes a seismic sensor 304 configured to provide an electronic signal 348 corresponding to seismic energy 306 incident thereto. The electronic signal 348 is coupled from the sensor 304 to the controller 302. In turn, the controller 302 is configured to digitally quantify the signals 348 and to store the resulting seismic data 332 within a data storage media 308. The storage media 308 can include any suitable computer-accessible data storage such as non-volatile memory, solid-state memory, magnetic storage media, optical storage media, and so on. Other types of storage media 308 can also be used.

The seismic sensor node 300 also includes a wireless receiver, typically a global positioning system (GPS) receiver 314, configured to receive global time values by way of wireless signals 316. Wireless signals 316 may be substantially equivalent to wireless signals 122. The GPS receiver 314 consumes a significant amount of electrical power during operation. The seismic sensor node 300 also includes a wireless transceiver 318 configured to perform bidirectional communication, over the mesh network, between the node 300 and various external entities by way of wireless signals 320. Wireless signals 320 may be substantially equivalent to wireless signals 126. Over a given time period, acquiring time information via the wireless transceiver 318 typically consumes significantly less power than acquiring time information via the GPS receiver 314. The GPS receiver 314 typically takes between several seconds and almost one minute to power up and acquire time information, while the wireless transceiver 318 can power up, receive a timing beacon, and retransmit the beacon much more quickly. Thus, even in configurations where the wireless transceiver 318 is used to acquire time beacons more frequently than the GPS receiver 314 would be used to acquire time information, the total amount of power consumed by the wireless transceiver 318 would be significantly less than that consumed by the GPS receiver 314.

The node 300 further includes a local clock 310. The local clock is configured to provide a local time value to the controller 302. The local clock 310 can be specifically defined by any suitable electronic circuitry, a dedicated purpose integrated circuit, and so on. The local clock 310 is also configured to be reset or resynchronized from time to time by way of the controller 302. Other suitable clocks can also be used. The local clock 310 of one node 300 is typically not synchronized to the local clock 310 of another node 300. The clock is typically driven by an oscillator 312. In one example, the oscillator 312 may be a low jitter temperature-compensated crystal oscillator. However, the clock 310 is typically not synchronized to global time, and may exhibit rate error relative to global time. As defined herein and in the appended claims, the term “rate error” shall be broadly understood to mean how much faster or slower the local clock is running compared to global time, often represented in parts per million. The output frequency of oscillator 312 typically varies with temperature and other factors, and is therefore not constant.

To compensate for this deviation in the rate error of the local clock 310 within a node 300, the node 300 intermittently receives global time (or a signal from which global time can be derived) from an external source, and then generates a timestamp that includes the global time and the corresponding local time. In one example, this may occur approximately every 10 to 20 seconds. The controller 302 is configured to receive or acquire GPS time values 342 by way of the GPS receiver 314. However, the GPS receiver 314 consumes a substantial amount of power, and operating the GPS receiver 314 to receive global time this frequently would undesirably shorten the time to replenishment or replacement of the power source 324. In order to conserve power by not operating the GPS receiver 314, the controller 302 acquires beacon time values 344 by way of the wireless transceiver 318 more frequently than via the GPS receiver 314. The controller 302 determines the latency 336 of beacon time transmission through the transmitter of the upstream node, the air, and the receiver of the receiving node. Then, using the determined latency 336, each beacon time 344 is converted to the corresponding global time.

The controller 302 is further configured to generate, for each of the beacon times 344, a timestamp 334 that includes the computed global time corresponding to the beacon time 344 and a local time 346 provided by the local clock 310. Such timestamps 334 are stored to the storage media 308 by the controller 302.

A set of the wireless sensor node 300 can be distributed over a and surface area such that a sensing array is defined. Each sensor node (e.g., node 300) operates autonomously and without hardwired connection to a central data acquisition hub. Each sensor node senses incident seismic energy 306 and stores, on the storage media 308, seismic data 332 that includes the corresponding local time. Seismic data measurement and storage is typically performed at regular intervals. The storage of the seismic data 332 and the storage of the timestamps 334 is performed asynchronously. That is, the storage of each seismic data 332 is not necessarily accompanied by, or contemporaneous with, the storage of a corresponding timestamp 334.

The stored seismic data 332 and timestamps 334 may later be retrieved from the storage media 308 and communicated to an entity distinct from the seismic sensor node 300 by wired, wireless, or other signaling. The onboard storage media 308 within the node 300 can then be erased, written over, or otherwise reused. In this way, a vast array of wireless seismic sensor nodes 300 can be deployed for field operation without having interconnecting wiring for electrical power, data acquisition or time clock synchronization.

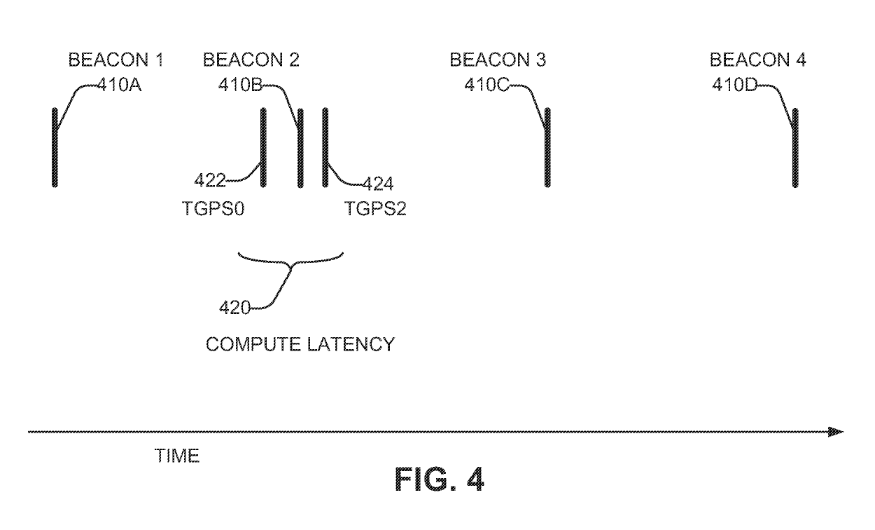

Considering beacon time in greater detail, and with reference to FIG. 4 in addition to FIG. 3, timing beacons 410 may be transmitted intermittently from an upstream node and received at a receiving node. The example beacon reception sequence of FIG. 4 illustrates four such timing beacons 410A-D. A node may send a beacon 410 periodically, in response to receiving a beacon from an upstream node, or in response to other events such as, for example, a change in network topology in the path of the node.

In one example, the beacon time 344 associated with each timing beacon 410 is implemented via the time synchronization function (TSF) of an 802.11 wireless transceiver, such as wireless transceiver 318 of node 300. In the sending node, the TSF counter may be set to the global time of the sending node, and thus the TSF counter becomes the beacon time. Alternatively, a global time offset value may be calculated that relates the TSF counter to the global time of the sending node, and thus the beacon time is equivalent to the TSF counter plus the global time offset value. In other examples, the beacon time 344 may be implemented using a function or a type of data frame other than TSF.

After each beacon 410A-D is received, the controller 302 of node 300 uses the previously determined value of the latency 336 to convert the received beacon time 344 of each timing beacon 410 to global time, and records a new timestamp 334 of the global time and the local time 346.

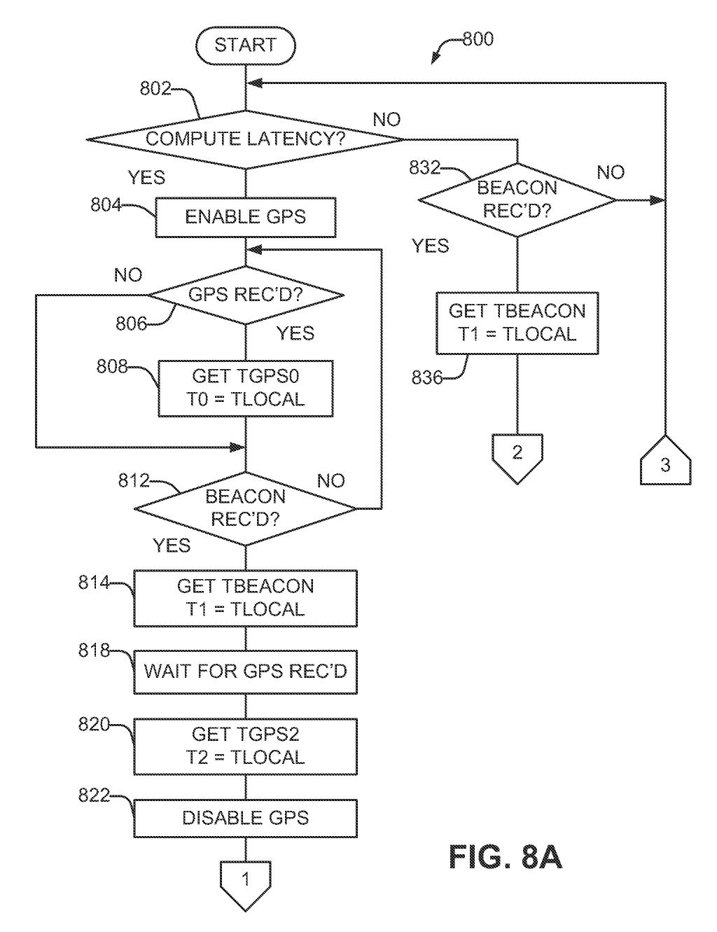

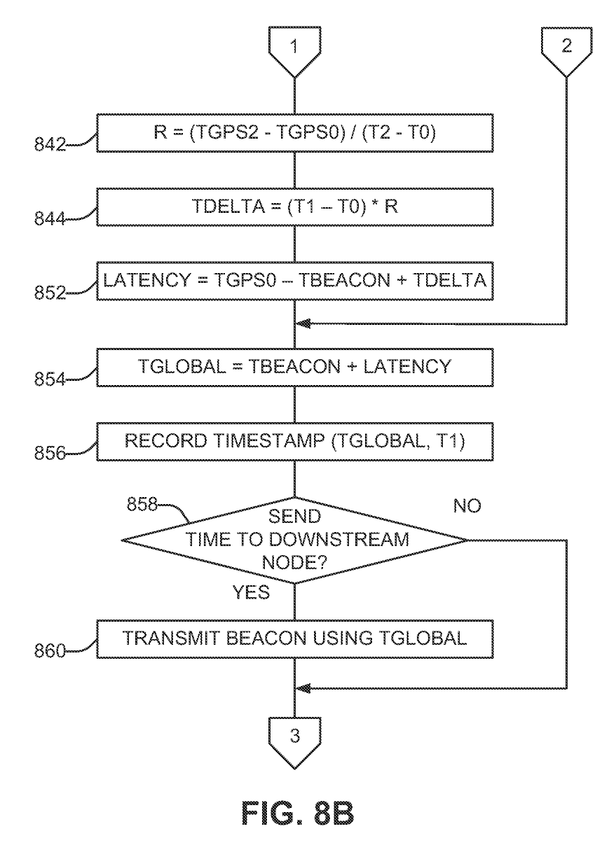

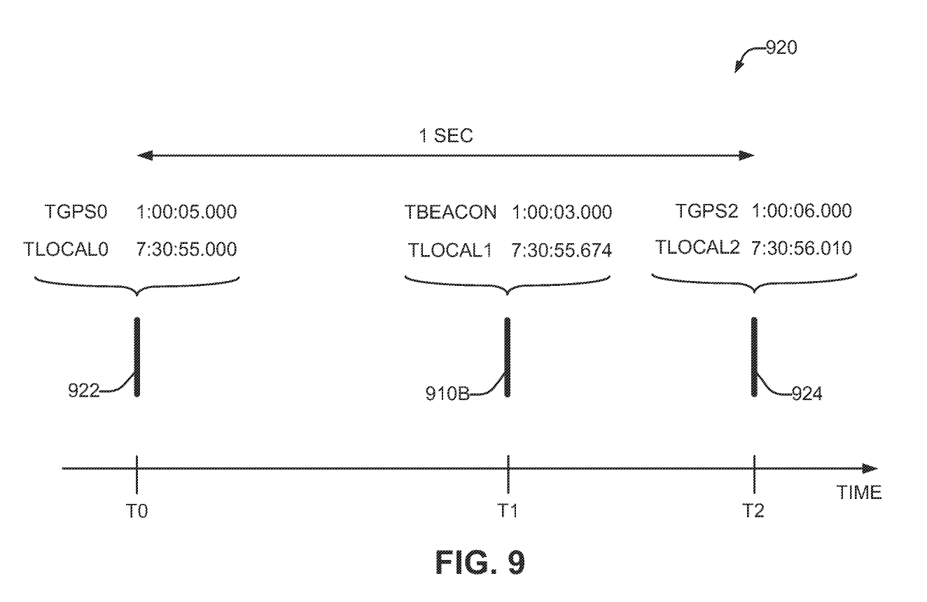

The controller 302 of node 300 may, on occasion, decide to recompute the latency 336. The decision may be based on the length of time since the last latency recomputation, or the occurrence of some event in the node 300 or in the mesh network. In the example beacon transmission sequence of FIG. 4, assume that at some point after reception of beacon1 410A and prior to the reception of beacon2 410B, the controller 302 of node 300 determines that the latency 336 is to be recomputed. The events in region 420 are associated with this recomputation. The GPS receiver 314 is enabled for a short period of time. The GPS receiver 314 typically provides a pulse per second (PPS) signal that is highly reliable and substantially jitter-free. As will be discussed subsequently in greater detail with reference to FIGS. 8A-8B and 9A-9B, the beacon time is correlated to GPS time 422, or to two GPS times 422, 424, by the controller 302 in order to recompute the latency 336 between beacon time and global time.

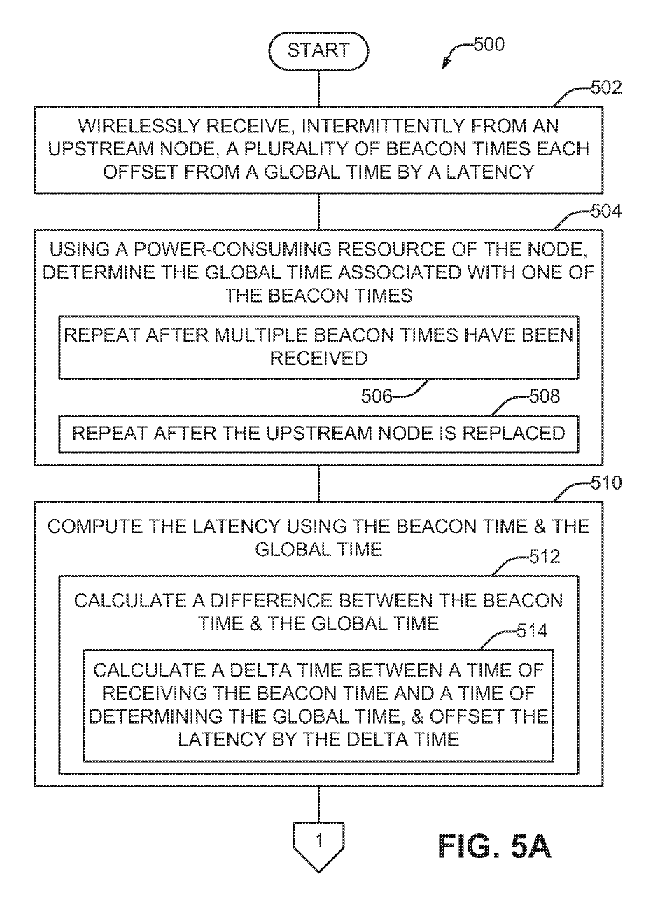

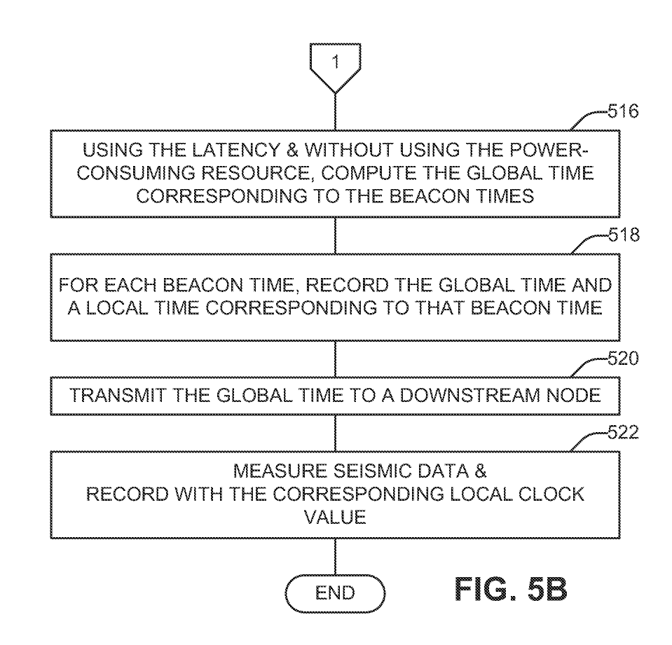

Consider now, and with reference to FIGS. 5A-B, a flowchart of a wireless seismic sensor node, or more particularly, a controller thereof. In one example, the wireless seismic sensor node may be node 300, and the controller may be controller 302. Alternatively, the flowchart of FIGS. 5A-B may be considered as steps in a method implemented in a wireless seismic sensor node or controller thereof. A method 500 begins at 502 by wirelessly receiving at the node, intermittently from an upstream node in the mesh, a plurality of beacon times each offset from a global time by a latency. At 504, using a power-consuming resource of the node, such as for example a GPS receiver, the global time associated with a selected one of the beacon times is determined. At 510, the latency is computed using the selected beacon time and the global time. In some examples, at 512, the latency is computed by calculating a difference between the selected beacon time and the global time. In some further examples, computing the latency also includes, at 514, calculating a delta time between a first time corresponding to receiving the selected beacon time and a second time corresponding to determining the associated global time, and offsetting the latency by the delta time. In some examples, the latency may be calculated according to the formula:

Latency=Global Time−Beacon Time+Delta Time

At 516, the global time corresponding to at least some of the beacon times is computed using the latency. However, the power-consuming resource is not used. At 518, for each beacon time, the global time and a local time corresponding to that beacon time are recorded. In some examples, at 520, the global time is transmitted from the sensor node to a downstream node in the mesh. In some examples, at 522, seismic data is measured using a sensor in the node, and the seismic data is recorded together with the local clock value that corresponds to the seismic data measurement.

In some examples, determining the global time using the power consuming resource may be repeated, at 506, after multiple beacon times have been wirelessly received. In other examples, determining the global time using the power-consuming resource may be repeated, at 508, after the upstream node in the mesh is replaced by a different upstream node.

It is noted that time information is transmitted through the mesh in one direction: from an upstream node to a receiving node. No time information is transmitted from the receiving node back to the upstream node. Furthermore, the local clocks of the upstream node and the receiving node are not time-synchronized to each other.

Some examples of the wireless sensor node 300 of FIG. 3 may also implement the method of FIGS. 5A-B.

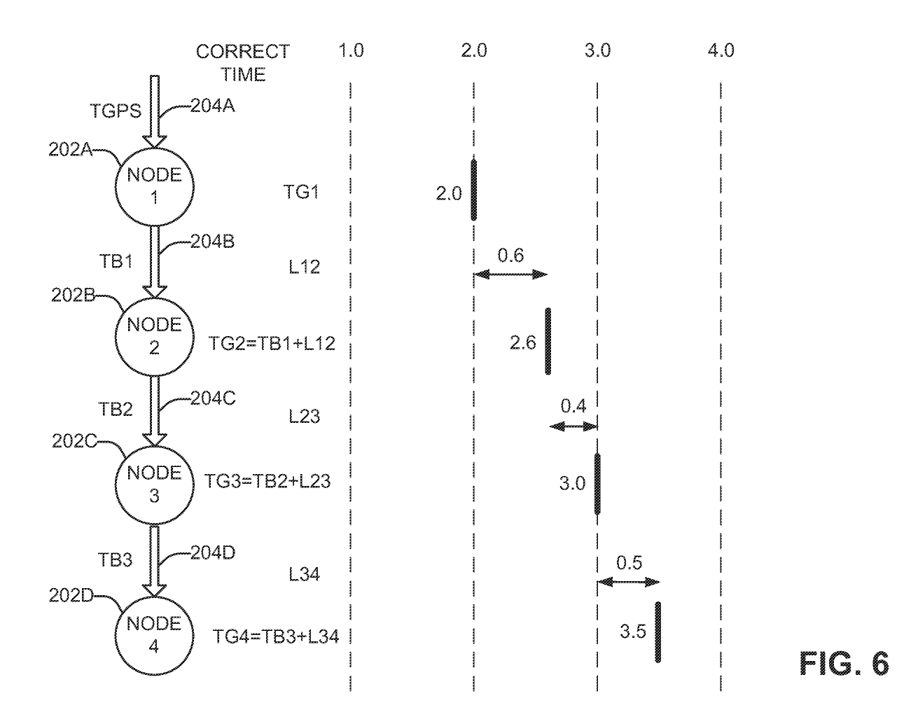

Considering now an example of the operation of the method 500 in a mesh network, and with reference to FIG. 6, beacon times can be utilized to relay or hop the correct global time between nodes in the network. FIG. 6 illustrates the four wireless sensor nodes 202A-D of FIG. 2. Assume that the latencies L12, L23, and L34 of the transmission of beacon times between the nodes 202A-D have been previously determined, as has been discussed with reference to FIGS. 4-5 and as will be further discussed with reference to FIGS. 8A-B and 9A-B. In this example operation, nodal 202A receives the correct global time TGPS 204A from its GPS receiver, and sets its internal global time TG1 to match it. The local clock of node1 202A increments the internal global time TG1 to track the correct global time. Then, at global time 2.0 seconds, node1 202A transmits to node2 202B the beacon time TB1 204B, which has the value of 2.0 seconds corresponding to its internal global time TG1. Node2 202B, upon receipt, sets its internal global time TG2 to 2.6 seconds, which is the sum of the beacon time TB1 204B plus the latency L12 of 0.6 seconds that occurs during the transmission between nodes. Next, node2 202B substantially immediately transmits to node3 202C the beacon time TB2 604C, which has the value of 2.6 seconds, corresponding to the internal global time TG2 of node2 202B. Node3 202C, upon receipt, sets its global time TG3 to 3.0 seconds, which is the sum of the beacon time TB2 604C plus the latency L23 of 0.4 seconds that occurs during the transmission between nodes. Finally, node3 202C substantially immediately transmits to node4 202D a beacon time TB3 604D, which has the value of 3.0 seconds, corresponding to the global time TG3 of node 3 202C. Node4 202D, upon receipt, sets its global time TG4 to 3.5 seconds, which is the sum of the beacon time TB3 604D plus the latency L34 of 0.5 seconds that occurs during the transmission between nodes. It can be seen that the internal global time values of the various nodes are all the correct global time. Thus the correct global time can advantageously be maintained at each node and updated through the intermittently reception of time beacons without operating the power-consuming GPS receiver in the node. In addition, because each node that receives a timing beacon from an upstream node corrects the beacon time to global time before sending a timing beacon, in turn, to a downstream node, a large number of nodes can exist in a path without significantly degrading the accuracy of global time maintained at each node.

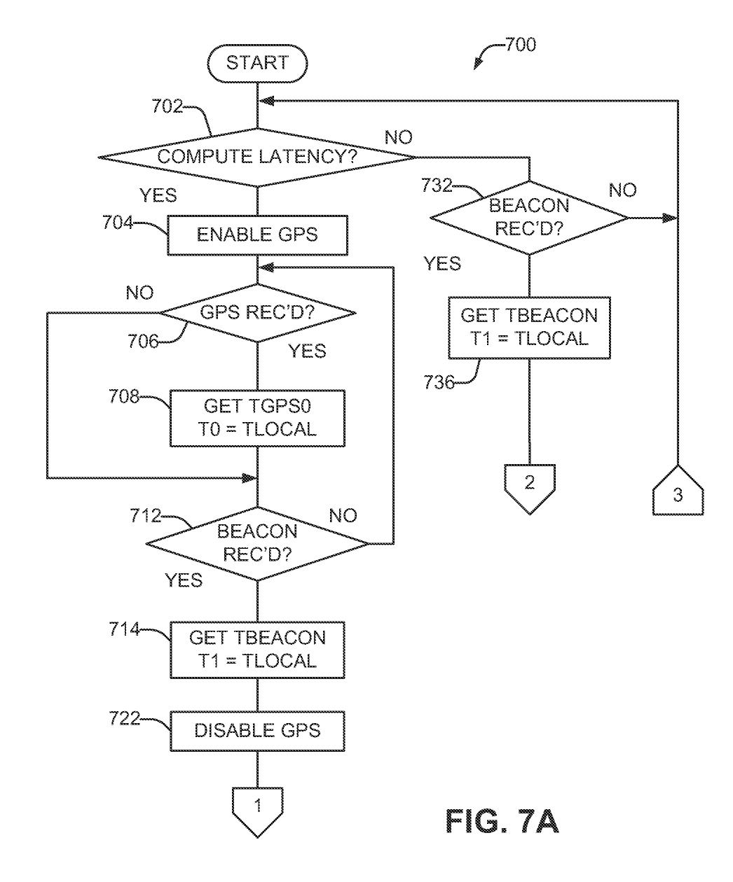

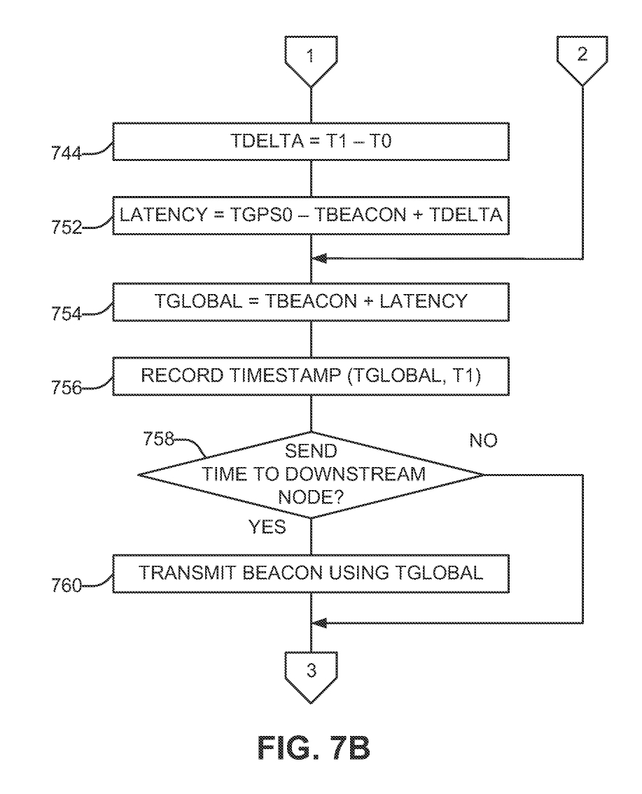

Consider now, and with reference to FIGS. 7A-B, another flowchart of a wireless seismic sensor node, or more particularly, a controller thereof. In one example, the wireless seismic sensor node may be node 300, and the controller may be controller 302. Alternatively, the flowchart of FIGS. 7A-B may be considered as steps in a method implemented in a wireless seismic sensor node or controller thereof.

Method 700 begins at 702 by determining whether the latency of time beacon transmission from an upstream node to the receiving node is to be computed or recomputed. If so (“Yes” branch of 702), then at 704 a GPS receiver in the receiving node is enabled. As has been discussed heretofore, the GPS receiver consumes a considerable amount of power during operation, and it is advantageous to minimize the amount of time it is in operation. At 706, it is determined whether a GPS pulse per second (PPS) signal generated by the GPS receiver has been received. This signal is typically generated once every second by the GPS receiver. If not, (“No” branch of 706), operation continues at 712. If the PPS signal has been received, then at 708 the GPS time corresponding to the PPS signal, referred to as TGPS0, is obtained from the GPS receiver, and the current time of the node's local clock is stored as T0. At 712, it is determined whether a timing beacon has been received from the upstream node by the wireless transceiver in the node. If not, (“No” branch of 712), then execution returns to 706. In environments where the timing beacon is received much less frequently than the PPS signal, such as once every 10 to 20 seconds, returning to 706 will obtain the GPS time corresponding to the next PPS such that, when the timing beacon is received, it will be within one second of the PPS signal.

If the timing beacon has been received (“Yes” branch of 712), then at 714 the beacon time corresponding to the timing beacon, referred to as TBEACON, is obtained from the wireless transceiver, and the current time of the node's local clock is stored as T1. At 722, since both the GPS time and the beacon time have been obtained, the GPS receiver is disabled to conserve node power.

At 744, TDELTA is calculated according to the formula:

TDELTA=T1−T0

At 752, the latency of time beacon transmission from an upstream node to the receiving node is computed according to the formula:

LATENCY=TGPS0−TBEACON−TDELTA

At 754, the global time corresponding to the beacon time is calculated according to the formula:

TGLOBAL=TBEACON+LATENCY

At 756, a timestamp corresponding to the timing beacon is recorded. The timestamp includes the global time, TGLOBAL, and the local clock at the time the timing beacon was received, T1. The timestamp is typically stored as a record in a timestamp database in the node such as, for example, timestamps 334 of node 300.

At 758, it is determined whether the node that has received the timing beacon from the upstream node has been configured to transmit global time to a downstream node in the mesh network. If so, and if it is to do so at the present time (“Yes” branch of 758), then at 760 a timing beacon is configured to transmit a timing beacon to the downstream node, using TGLOBAL as the time value for TBEACON. Following this, or if the node does not transmit global time to a downstream node at the present time (“No” branch of 758), the method returns to 702.

If, at 702, the latency is not to be computed or recomputed (“No” branch of 702), then at 732 it is determined whether a timing beacon has been received from the upstream node by the wireless transceiver in the node. If not (“No” branch of 732), the method returns to 702. If the timing beacon has been received (“Yes” branch of 732), then at 736 the beacon time corresponding to the timing beacon, referred to as TBEACON, is obtained from the wireless transceiver, the current time of the node's local clock is stored as T1, and the method branches to 754 to compute TGLOBAL using the previously-determined value of latency.

Considering now the operation of the method 700, and with reference to FIG. 9, example time values for global, beacon, and local time are defined that illustrate the operation. FIG. 9 illustrates events that occur in a region 920 during the computation of latency (“Yes” branch of 702). In one example, these events correspond to the events of region 420 (FIG. 4). Event 922 indicates generation of a PPS signal by the GPS receiver of the node as detected at step 706. The value of the GPS time corresponding to the PPS signal obtained at step 708 (TGPS0) is 1:00:05.000, where the time is represented in HH:MM:SS.SSS format. The value of the node's local clock at time T0 (TLOCAL0), obtained at step 708, is 7:30:55.000. It is noted that local clock time and GPS time are quite different and not synchronized to each other. Furthermore, the local clock times of the node are not synchronized to the local clock times of the upstream node.

Event 910B indicates reception of a timing beacon by the wireless transceiver of the node as detected at step 712. The value of the beacon time obtained at step 714 is 1:00:03.00. The value of the node's local clock at time T1 (TLOCAL1), obtained at step 714, is 7:30:55.674.

These example values for TGPS0, TLOCAL0, TBEACON, and TLOCAL1 are used in subsequent calculations. TDELTA, computed using the formula of 744, is 0.674. LATENCY, computed using the formula of 752, is 2.674. Finally, the global time TGLOBAL corresponding to timing beacon 910B, computed using the formula of 754, is 1:00:05.674.

Consider now, and with reference to FIGS. 8A-B, yet another flowchart of a wireless seismic sensor node, or more particularly, a controller thereof. In one example, the wireless seismic sensor node may be node 300, and the controller may be controller 302. Alternatively, the flowchart of FIGS. 9A-B may be considered as steps in a method implemented in a wireless seismic sensor node or controller thereof.

Relative to the method of FIGS. 7A-B, the method of FIGS. 8A-B includes a calculation of a correction factor for the rate error of the local clock of a node, and uses the correction factor to determine the latency somewhat more accurately. The tradeoff involved is the consumption of more node power, since the GPS receiver is operated for a somewhat longer period of time.

Method 800 begins at 802 by determining whether the latency of time beacon transmission from an upstream node to the receiving node is to be computed or recomputed. If so (“Yes” branch of 802), then at 804 a GPS receiver in the receiving node is enabled. As has been discussed heretofore, the GPS receiver consumes a considerable amount of power during operation, and it is advantageous to minimize the amount of time it is in operation. At 806, it is determined whether a GPS pulse per second (PPS) signal generated by the GPS receiver has been received. This signal is typically generated once every second by the GPS receiver. If not, (“No” branch of 806), operation continues at 812. If the PPS signal has been received, then at 808 the GPS time corresponding to the PPS signal, referred to as TGPS0, is obtained from the GPS receiver, and the current time of the node's local clock is stored as T0. At 812, it is determined whether a timing beacon has been received from the upstream node by the wireless transceiver in the node. If not, (“No” branch of 812), then execution returns to 806. In environments where the timing beacon is received much less frequently than the PPS signal, such as once every 10 to 20 seconds, returning to 806 will obtain the GPS time corresponding to the next PPS such that, when the timing beacon is received, it will be within one second of the PPS signal.

If the timing beacon has been received (“Yes” branch of 812), then at 814 the beacon time corresponding to the timing beacon, referred to as TBEACON, is obtained from the wireless transceiver, and the current time of the node's local clock is stored as T1. At 818, the method waits until another PPS signal is received. At 820, once the PPS signal has been received, the GPS time corresponding to this additional PPS signal, referred to as TGPS2, is obtained from the GPS receiver, and the current time of the node's local clock is stored as T2. At 822, since the two GPS times and the beacon time have all been obtained, the GPS receiver is disabled to conserve node power.

At 842, the correction factor R for the rate error of the local dock is calculated according to the formula:

R=(TGSP2−TGSP0)/(T2−T0)

At 844, TDELTA is calculated according to the formula:

TDELTA=(T1−T0)*R

At 852, the latency of time beacon transmission from an upstream node to the receiving node is computed according to the formula:

LATENCY=TGPS0−TBEACON+TDELTA

At 854, the global time corresponding to the beacon time is calculated according to the formula:

TGLOBAL=TBEACON+LATENCY

At 856, a timestamp corresponding to the timing beacon is recorded. The timestamp includes the global time, TGLOBAL, and the local dock at the time the timing beacon was received, T1. The timestamp is typically stored as a record in a timestamp database in the node such as, for example, timestamps 334 of node 300.

At 858, it is determined whether the node that has received the timing beacon from the upstream node has been configured to transmit global time to a downstream node in the mesh network. If so, and if it is to do so at the present time (“Yes” branch of 858), then at 860 a timing beacon is configured to transmit a timing beacon to the downstream node, using TGLOBAL as the time value for TBEACON. Following this, or if the node does not transmit global time to a downstream node at the present time (“No” branch of 858), the method returns to 802.

If, at 802, the latency is not to be computed or recomputed (“No” branch of 802), then at 832 it is determined whether a timing beacon has been received from the upstream node by the wireless transceiver in the node. If not (“No” branch of 832), the method returns to 802. If the timing beacon has been received (“Yes” branch of 832), then at 836 the beacon time corresponding to the timing beacon, referred to as TBEACON, is obtained from the wireless transceiver, the current time of the node's local clock is stored as T1, and the method branches to 854 to compute TGLOBAL using the previously-determined value of latency.

Considering now the operation of the method 800, and with reference to FIG. 9, example time values for global, beacon, and local time are defined that illustrate the operation. The example values for TGPS0, TLOCAL0, TBEACON, and TLOCAL1 are obtained in the same manner as has been described heretofore with reference to the operation of the method 700. However, method 800 uses additional values associated with a second, additional PPS signal acquired by the GPS receiver.

Event 924 indicates generation of the second, additional PPS signal by the GPS receiver of the node as detected at step 820. The value of the GPS time corresponding to the second PPS signal obtained at step 820 (TGPS2) is 1:00:06.000; the PPS signals are one second apart and highly accurate. The value of the node's local clock at time T2 (TLOCAL2), obtained at step 820, is 7:30:56.010. Thus it can be observed that the local clock of the node measures the time interval between the two PPS signals 922, 924, as 1.010 seconds, slightly greater than the correct time interval of 1.000 seconds. In other words, the local clock is running slightly fast.

These example values for TGPS0, TLOCAL0, TBEACON, TLOCAL1, TGPS2, and TLOCAL2 are used in subsequent calculations. The correction factor R for the rate error of the local clock, computed using the formula of 842, is 0.990. TDELTA, computed using the formula of 844, is 0.667. LATENCY, computed using the formula of 852, is 2.667. Finally, the global time TGLOBAL corresponding to timing beacon 910B, computed using the formula of 854, is 1:00:05.667.

From the foregoing it will be appreciated that the wireless sensor node and methods provided by the present disclosure represent a significant advance in the art. Although several specific examples have been described and illustrated, the disclosure is not limited to the specific methods, forms, or arrangements of parts so described and illustrated. This description should be understood to include all novel and non-obvious combinations of elements described herein, and claims may be presented in this or a later application to any novel and non-obvious combination of these elements. The foregoing examples are illustrative, and no single feature or element is essential to all possible combinations that may be claimed in this or a later application. Unless otherwise specified, steps of a method claim need not be performed in the order specified. The disclosure is not limited to the above-described implementations, but instead is defined by the appended claims in light of their full scope of equivalents. Where the claims recite “a” or “a first” element of the equivalent thereof, such claims should be understood to include incorporation of one or more such elements, neither requiring nor excluding two or more such elements.

What is claimed is:

1. A method of time-synchronizing a wireless sensor node of a mesh network, comprising:
wirelessly receiving at the node, intermittently from an upstream node in the network, a plurality of beacon times each offset from a global time by a latency;
using a power-consuming resource of the node, determining the global time associated with a selected one of the beacon times;
computing the latency using the selected beacon time and the global time;
using the latency and without using the power-consuming resource, computing the global time corresponding to at least some of the beacon times; and
for each beacon time, recording the global time and a local time corresponding to that beacon time.

2. The method of claim 1, wherein the latency includes an aggregate latency of a wireless transmitter in the upstream node and a wireless receiver in the sensor node.

3. The method of claim 1, wherein the power-consuming resource is a GPS receiver.

4. The method of claim 1, wherein the sensor node does not transmit any time value to the upstream node.

5. The method of claim 1, comprising:
transmitting the global time from the sensor node to a downstream node in the mesh.

6. The method of claim 1, wherein the determining the global time is repeated after multiple beacon times have been wirelessly received.

7. The method of claim 1, wherein the determining the global time is repeated after the upstream node in the mesh is replaced by a different upstream node.

8. The method of claim 1, comprising:
measuring seismic data using a sensor in the node; and
recording the seismic data together with the local clock value corresponding to the seismic data measurement.

9. The method of claim 1, wherein the computing the latency comprises:
calculating a difference between the selected beacon time and the global time.

10. The method of claim 9, wherein the computing the latency comprises:
calculating a delta time between a first time corresponding to receiving the selected beacon time and a second time corresponding to determining the associated global time; and
offsetting the latency by the delta time.

11. A wireless sensor node, comprising:
a wireless transceiver configured to intermittently receive beacon times from another node in a mesh network, each beacon time offset from a corresponding global time by a latency;
a wireless receiver configured to receive the global time without the latency;
a clock configured to provide a local ti and
a controller configured to
operate the wireless receiver to obtain the global time associated with a first beacon time,
compute the latency using the first beacon time and the corresponding global time,
using the latency, computing the global time corresponding to each of a set of subsequent beacon times without operating the wireless receiver, and
record, for each beacon time, a timestamp of the global time and the corresponding local time.

12. The sensor node of claim 11, comprising:
a sensor configured to measure seismic energy incident to the sensor, the controller configured to record the measured seismic energy together with local time corresponding to the seismic energy measurement.

13. The sensor node of claim 12, wherein the controller records the measured seismic energy asynchronously from the recording of the timestamp.

14. The sensor node of claim 11, wherein the sensor node does not transmit any time value to the another node.

15. The sensor node of claim 11, wherein the clock of the sensor node is not synchronized to a clock of the another node.

16. The node of claim 11, wherein the controller is further configured to compute the latency by:
calculating a delta time between the receipt of the first beacon time and the obtaining of the global time associated with the first beacon time; and
calculating the latency according to the formula: latency=global time−beacon time+delta time.

17. The node of claim 11, wherein the recorded seismic energy measurements and the recorded timestamps are processed external to the sensor node in order to correlate the energy measurements to global time.

18. A method of time-synchronizing data from wireless sensor nodes in a mesh network, comprising:
providing an upstream node with an upstream local time not synchronized to a downstream local time of a downstream node;
correlating, at the upstream node, the upstream local time to a global time;
wirelessly transmitting a beacon time equal to the global time from the upstream node to the downstream node;
wirelessly receiving the beacon time at the downstream node, the received beacon time value from the global time by a latency of the transmitting and the receiving;
determining the latency at the downstream node; and
at the downstream node, using the global time and the latency to correlate the downstream local time to the global time.

19. The method of claim 18, wherein the upstream and downstream local times are not synchronized.

20. The method of claim 18, wherein the downstream node does not transmit any time to the upstream node.
